(19) United States
(12) Patent Application Publication
(10) Pub. No.: US 2021/0225624 A1
(43) Pub. Date: Jul. 22, 2021

(54) MAGNETRON SPUTTERING EQUIPMENT

(71) Applicant: Miasolé Equipment Integration (Fujian) Co., Ltd., Quanzhou, Fujian (CN)

(72) Inventors: Yang Liu, Quanzhou, Fujian (CN); Zhennan Wang, Quanzhou, Fujian (CN); Shaowen Lei, Quanzhou, Fujian (CN); Yonglei Yang, Quanzhou, Fujian (CN); Dongwei Jian, Quanzhou, Fujian (CN); Wei Zhang, Quanzhou, Fujian (CN); Ying Wu, Quanzhou, Fujian (CN); Fushan Liu, Quanzhou, Fujian (CN); Xiaolin Han, Quanzhou, Fujian (CN)

(73) Assignee: Miasolé Equipment Integration (Fujian) Co., Ltd., Quanzhou, Fujian (CN)

(21) Appl. No.: 16/308,407

(22) PCT Filed: Sep. 13, 2018
(86) PCT No.: PCT/CN2018/105426

§ 371 Date: Dec. 7, 2018

(30) Foreign Application Priority Data
Jun. 22, 2018 (CN) 20182096086.2

(51) Int. Cl. H01J 37/34; C23C 14/35

(52) U.S. Cl. CPC H01J 37/3405; H01J 2237/081; C23C 14/35

(57) ABSTRACT

The present disclosure provides a magnetron sputtering equipment, including: a mesh shielding plate disposed in a vacuum chamber of the magnetron sputtering equipment; the vacuum chamber includes one or more coating chambers, and the mesh shielding plate is disposed on a sidewall within the coating chamber, which facilitates the smooth operation of the magnetron sputtering target, and avoids the gas pollution of the vacuum chamber, and the installation and disassembly are simple and fast. The present disclosure provides an important solution and approach for a production line of the magnetic sputtering equipment.

### CROSS-REFERENCE TO RELATED APPLICATIONS

This application is a national stage application under U.S.C. § 371 of PCT Application No. PCT/CN2018/105426, filed Sep. 13, 2018, which claims to foreign priority benefits under 35 U.S.C. 119(a)-(d) or 35 U.S.C. 365(b) of Chinese Patent Application No. 201820969086.2, filed Jun. 22, 2018, the entire contents of each of which are incorporated herein by reference in their entireties.

### TECHNICAL FIELD

The present disclosure relates to the field of magnetron sputtering, and more particularly, to a magnetron sputtering equipment.

### BACKGROUND

Magnetron sputtering is mainly used for coating and has a wide range of applications in various fields. The magnetron sputtering introduces a magnetic field on the surface of the cathode of target, and takes advantage of magnetic field constraint on charged particles to increase the plasma density, so as to increase the sputtering rate. The magnetron sputtering has the advantages of simple equipment, low substrate temperature, easy control, high film formation rate, large coating area, strong adhesion and the like.

The conventional domestic magnetron sputtering equipment adopts a flat protection plate. In such conventional structure, after the vacuum coating chamber operates for a period of time, a large amount of sputtering deposits are formed, which accumulate in the vicinity of the sputtering target and affect the normal operation of the sputtering target, in severe cases, the sputtering target strikes sparks. When there are lots of deposits, the atmosphere in the vacuum chamber is unclean, causing a decrease in vacuum degree and causing a production quality decrease or failure.

The vacuum chamber of the current magnetron sputtering equipment has the following disadvantages: 1. because the protection plate is fixed on the vacuum chamber door and close to the sputtering target attachment, the deposits formed during the production is prone to cracking, wrinkling, and falling off, which easily cause the sputtering target to strike sparks; 2. the vacuum chamber is thin on both sides, the anti-electromagnetic interference ability is weak, and the electromagnetic shielding effect is poor.

### SUMMARY

In one embodiment, the present disclosure provides a magnetron sputtering equipment, including: a mesh shielding plate disposed in a vacuum chamber of the magnetron sputtering equipment; wherein the vacuum chamber includes one or more coating chambers, and the mesh shielding plate is disposed on a sidewall within the coating chamber.

### BRIEF DESCRIPTION OF THE DRAWINGS

FIG. 1 is a structural schematic diagram of a vacuum chamber of a magnetron sputtering equipment according to an embodiment of the present disclosure;

FIG. 2 is a structural schematic diagram of a mesh shielding plate according to an embodiment of the present disclosure, wherein (a) of FIG. 2 shows a front view of the mesh shielding plate, and (b) of FIG. 2 shows a plan view of the mesh shielding plate;

FIG. 3 is a structural schematic diagram of a vacuum chamber of a magnetron sputtering equipment having one coating chamber according to an embodiment of the present disclosure;

FIG. 4 is a structural schematic diagram of a vacuum chamber of a magnetron sputtering equipment having two coating chambers according to an embodiment of the present disclosure; and

FIG. 5 is a structural schematic diagram of a vacuum chamber of a magnetron sputtering equipment having four coating chambers according to an embodiment of the present disclosure.

### DETAILED DESCRIPTION

In order to make the aims, technical solutions and advantages of the present disclosure more clear, the present disclosure will be further described in detail below with reference to the specific embodiments and the accompanying drawings. It is to be understood that the description is only illustrative, and is not intended to limit the scope of the disclosure. In addition, descriptions of well-known structures and techniques are omitted in the following description in order to avoid unnecessary confusion of the concept of the present disclosure.

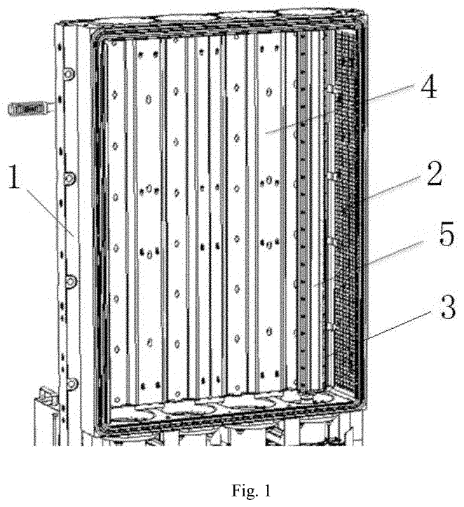

FIG. 1 is a structural schematic diagram of a vacuum chamber of a magnetron sputtering equipment according to an embodiment of the present disclosure. As shown in FIG. 1, a magnetron sputtering equipment according to an embodiment of the present disclosure includes: a mesh shielding plate 2 disposed in a vacuum chamber 1 of the magnetron sputtering equipment; wherein the vacuum chamber 1 includes one or more coating chambers 3 therein, and the mesh shielding plate 2 is disposed on a sidewall inside the coating chamber 3.

In an example, the vacuum chamber 1 is in a shape of a rectangular parallelepiped, or a cube, and the vacuum chamber 1 provides magnetron sputtering conditions for the magnetron sputtering equipment and also provides mounting locations for components within the vacuum chamber 1.

Optionally, the mesh shielding plate 2 is disposed on opposite sides within the vacuum chamber 1 (left and right sides of FIG. 1). In general, some of inner walls of the vacuum chamber 1 for magnetron sputtering are thin and some of the inner walls of the vacuum chamber 1 for magnetron sputtering are thick, and the thin inner wall of the vacuum chamber 1 is easily disturbed by an external magnetic field and has a poor resistance to electromagnetic interference. For this, the mesh shielding plate 2 is provided on the thin inner wall of the vacuum chamber 1 so as to provide a better electromagnetic shielding effect. Generally, the opposite sides of the vacuum chamber 1 are relatively thin, and the mesh shielding plates are disposed on the inner walls of the two sides, which greatly enhances the electromagnetic shielding effect on the two sides.

The coating chamber 3 provides a coating reaction environment for the magnetron sputtering equipment. Generally, there are a plurality of coating chambers 3. Optionally, the number of the coating chamber 3 is any of 1 to 6, and for instance, the number of the coating chamber 3 is 4.

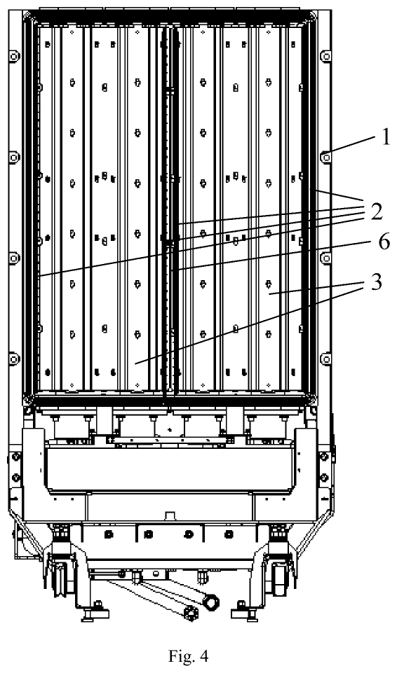

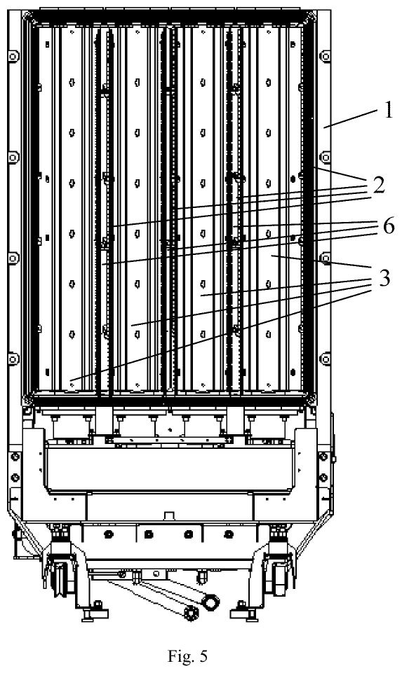

In an example, as shown in FIG. 4 and FIG. 5, the coating chamber 3 is formed by separating the vacuum chamber 1 by one or more parallel partition plates 6.

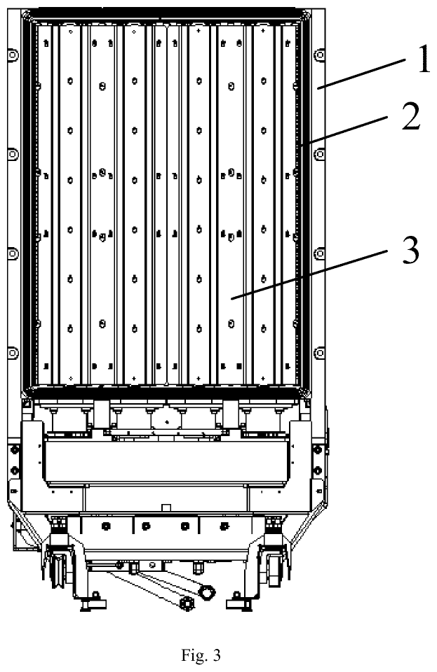

As shown in FIG. 3, when the number of the coating chamber 3 is 1, the vacuum chamber 1 is the coating chamber 3, and the mesh shielding plate 2 is disposed on the inner walls at the opposite sides in the vacuum chamber 1. As shown in FIG. 4, when the number of the coating chambers 3 is 2, the coating chambers 3 are formed by separating the vacuum chamber 1 by a partition plate 6, and the mesh shielding plates 2 are respectively disposed on the sidewalls within the formed two coating chambers 3, that is, the mesh shielding plates 2 are respectively disposed on opposite sides of each coating chamber 3, that is, on both sides of the partition plate 6 and on opposite sides in the vacuum chamber 1.

As shown in FIG. 5, when the number of the coating chambers 3 is 4, the coating chambers 3 are formed by separating the vacuum chamber 1 by three parallel partition plates 6, and the mesh shielding plates 2 are respectively disposed on the sidewalls in the formed four coating chambers 3, that is, the mesh shielding plates 2 are respectively disposed on opposite sides of each coating chamber 3, that is, on both sides of each of the partition plates 6 and on opposite sides in the vacuum chamber 1.

By arranging the mesh shielding plates 2 on the sidewalls in the coating chamber 3 respectively, the external electromagnetic interference is isolated, the electromagnetic shielding effect in the coating chamber 3 is enhanced, the electrons and ions in the vacuum chamber are ensured to work normally, and the quality of magnetic sputtering is improved.

On the other hand, the mesh shielding plate 2 has a large surface friction due to its mesh shape, which can strongly constrain the sputtered deposits, so that the deposits can be adhered to the surface of the mesh shielding plate 2 for a long time. The mesh of the mesh shielding plate 2 constrains the sputtered deposits, and then the sputtered deposits are restrained from flying to affect the smooth progress of the magnetron sputtering work. In addition, due to the arrangement of the mesh shielding plate 2, the sputtered deposits are attached to the mesh plate, and are not easily cracked, wrinkled, and peeled off after being stacked together. Thereby, the stability and yield rate of the whole equipment are improved, and the gas pollution in the vacuum chamber 1 is prevented, which provides space and time for good operation of magnetron sputtering for a long time.

In an example, as shown in FIG. 1, a sidewall in the coating chamber 3 is further provided with a protection plate 4, wherein the mesh shielding plate 2 is disposed outside the protection plate 4, i.e., at a side of the protection plate 4 which is not adjacent to the sidewall within the coating chamber (3).

Optionally, the protection plate 4 is disposed on all inner walls of the vacuum chamber 1 and the sidewalls in the coating chamber 3, for example, the protection plate 4 is disposed on both sides of the partition plate and the opposite sidewalls in the vacuum chamber 1 parallel to the partition plate. In this way, a complete electromagnetic shielding space for shielding electromagnetic and isolating external electromagnetic interference is formed. On the other hand, the magnetron sputtering target 5 produces deposits, and the protection plate 4 may be used to block the deposits generated during sputtering, and deposit the deposits on the protection plate to prevent the deposits from depositing on the inner walls of the vacuum chamber 1. Therefore, the gas in the vacuum chamber 1 is prevented from being contaminated, thereby ensuring the quality of the coating and the stability of the equipment; in addition, since the installation and disassembly of the protection plate 4 are very simple, the cleaning thereof is also very simple.

In addition, on the basis of the electromagnetic shielding of the protection plate 4, the mesh shielding plate 2 is further added, then a space is formed between the protection plate 4 and the mesh shielding plate 2. When the sputtered deposits enter the space between the protection plate 4 and the mesh shielding plate 2 through the meshes of the mesh shielding plate 2, the sputtered deposits are locked for a long time in a gap formed between the protection plate 4 and the mesh shielding plate 2, and the sputtered deposits do not easily crack, wrinkle, and fall off, therefore the stability and yield rate of the entire equipment are greatly improved, and gas pollution in the vacuum chamber 1 is prevented, which provides space and time for long-term magnetron sputtering.

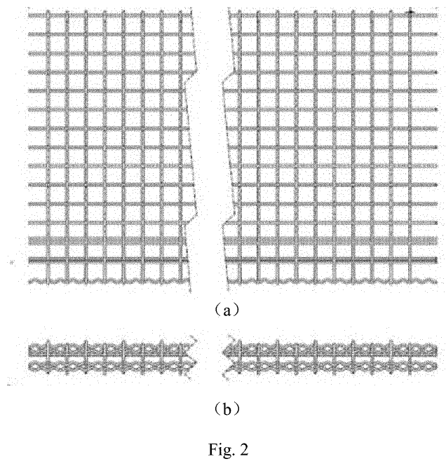

FIG. 2 is a structural schematic diagram of a mesh shielding plate according to an embodiment of the present disclosure. As shown in FIG. 2, the mesh shielding plate 2 is a mesh plate made of a copper alloy wire by cross knitting (cross weaving). (a) in FIG. 2 shows a front view of the mesh shielding plate, and (b) of FIG. 2 shows a plan view of the mesh shielding plate. Thus, it is possible to ensure the structural strength of the shielding plate body 2 is enhanced, and the stability of the shielding performance is improved.

Optionally, the copper alloy wire has a diameter of 1 to 2 mm.

Optionally, the mesh shielding plate 2 is formed by intersecting the copper alloy wires at a certain angle and fixedly connecting the copper alloy wires at the junctions by spot welding, pressing, knotting, etc., i.e., a mesh plate is formed. The meshes of the formed mesh plate may have a shape of square, rectangular, prismatic, irregular quadrangular or the like. In an example, the mesh shielding plate 2 may be formed by placing the copper alloy wires in a horizontal direction and a vertical direction respectively and fixedly connecting the copper alloy wires at the junctions to form a mesh plate having a mesh side length of 0.07 to 4 mm.

Optionally, the protection plate 4 is a metal plate, such as a steel plate.

In an example, the protection plate 4 is a 316L stainless steel plate.

Optionally, the protection plate 4 has a thickness of 1.2 to 1.8 mm, such as 1.5 mm.

In an example, the protection plate 4 may be assembled by assembling steel plate modules having a thickness of 1.5 mm. The production and installation process are relatively simple, and it is suitable for projects with small area and high shielding performance requirements.

In an example, an inner wall(s) of the vacuum chamber 1 is provided with a mounting hole(s) for mounting the mesh shielding plate 2.

Optionally, the protection plate 4 is provided with a mounting hole(s) for mounting the protection plate 4.

In an example, the mounting hole has a bore diameter of 3 to 5 mm, such as 4 mm.

In an example, the mounting holes of the protection plate 4 and the vacuum chamber 1 may be threaded holes.

Optionally, during installation, the mesh shielding plate and the protection plate 4 may be fixed to the inner walls of the vacuum chamber 1 and the sidewalls in the coating chamber 3 only by inserting the screw into the mesh of the mesh shielding plate 2, the mounting hole of the protection plate 4, and the mounting hole on the inner wall of the vacuum chamber 1. During disassembly, the mesh shielding plate 2 and the protection plate 4 may be disassembled by simply removing the screw. It may be seen that the installation and disassembly of the mesh shielding plate 2 and the protection plate 4 are very convenient, and it enables rapid assembling.

In an example, upper and lower inner walls of the coating chamber 3 are provided with fixing members for fixing the mesh shielding plate 2.

Optionally, the fixing members may be a clamping structure, such as a clamping slot.

In an embodiment, sliding slots are provided at the upper and lower inner walls of the coating chamber 3 respectively, sliding rails are provided at two ends of the mesh shielding plate, which are corresponding to the upper and lower inner walls of the coating chamber respectively, and the sliding slots and the sliding rails are connected in a sliding way. Thereby, it is very convenient for the pick-and-place of the mesh shielding plate 2 by the sliding connection.

In another embodiment, the upper and lower inner walls of the coating chamber 3 are provided with a hanging member, and the mesh shielding plate 2 and the coating chamber 3 are connected by the hanging member. It is very convenient to pick up and place the mesh shielding plate 2 through the connection of the hanging member.

Optionally, a magnetron sputtering target 5 is disposed in the coating chamber 3, for example, one or more magnetron sputtering targets 5 are disposed in one coating chamber 3, and for instance, one magnetron sputtering target 5 is disposed in one coating chamber 3.

Optionally, the magnetron sputtering target 5 is a rotatable magnetron sputtering target.

In an example, as shown in FIG. 1, there are four coating chambers 3 in the vacuum chamber 1, one magnetron sputtering target 5 is disposed in each coating chamber 3, and each magnetron sputtering target 5 is sequentially arranged at equal intervals, for example, the interval value is 70 to 100 mm, such as 85 mm.

Optionally, the mesh shielding plate 2 and the magnetron sputtering target 5 are separated by a distance of 70 to 100 mm, such as 85 mm.

Optionally, the distance between the top of the magnetron sputtering target 5 and the upper inner wall of the vacuum chamber is 12-18 mm, such as 15 mm.

The magnetron sputtering target 5 per se generates a magnetic field, and the mesh shielding plate 2 is disposed on the opposite inner sidewalls in the coating chamber 3. On one hand, it may effectively shield the electromagnetic wave of the magnetron sputtering target 5; and on the other hand, it may enhance the electromagnetic shielding against external interfering electromagnetic waves, and ensure the uniformity and stability of the magnetic field of the magnetron sputtering target 5 and the normal work of the magnetron sputtering target.

In summary, the present disclosure aims to protect a magnetron sputtering equipment, on the basis of the protection plate 4, a mesh shielding plate 2 is provided, on one hand, it is convenient to collect deposits, and gas pollution in the vacuum chamber 1 and the coating chamber 3 may be avoided; on the other hand, it may enhance the electromagnetic shielding effect of the thin wall portion of the vacuum chamber 1, and shield the electromagnetic wave of the magnetron sputtering target 5 to achieve high electromagnetic shielding. The installation and disassembly of the magnetron sputtering equipment are simple. The mounting hole is reserved in the inner wall of the vacuum chamber 1, and the screw passes through the mounting hole to fix the protection plate 4 and the vacuum chamber 1 together, and before this, the mesh shielding plate 2 may also be fixed to the shielding plate. When disassembling, it is only needed to remove the screw, and the installation and disassembly are realized. It is very simple. Alternatively, a quick assembly of the protection plate 4 and the mesh shielding plate 2 in the sputtering vacuum chamber 1 may be achieved by a fixing member such as a clamping structure or an installation manner such as a sliding connection, a hanging member installation, etc., thereby avoiding the low efficiency, large error, easy to damage, easy to deform, pollution and other defects of the conventional method.

It should be understood that the above-described embodiments of the present disclosure are to be construed as illustrative and not restrictive. Therefore, any modifications, equivalents, improvements, etc., which are made without departing from the spirit and scope of the disclosure, are intended to be included within the protection scope of the present disclosure. In addition, the accompanying claims of the present disclosure are intended to cover all variations and modifications within the scope and boundaries of the accompanying claims or equivalent forms of such scope and boundaries.

1.-18. (canceled)

19. A magnetron sputtering equipment, comprising: a vacuum chamber and a mesh shielding plate, wherein the mesh shielding plate is disposed in the vacuum chamber; and
wherein the vacuum chamber comprises one or more coating chambers therein, and the mesh shielding plate is disposed on a sidewall within the coating chamber.

20. The magnetron sputtering equipment according to claim 19, wherein the sidewall of the coating chamber is further provided with a protection plate, and the mesh shielding plate is disposed at a side of the protection plate that is not adjacent to the sidewall within the coating chamber.

21. The magnetron sputtering equipment according to claim 19, wherein the mesh shielding plate is a mesh plate made of copper alloy wires by cross knitting.

22. The magnetron sputtering equipment according to claim 20, wherein the mesh shielding plate is a mesh plate made of copper alloy wires by cross knitting.

23. The magnetron sputtering equipment according to claim 21, wherein the copper alloy wires have a diameter of 1 to 2 mm.

24. The magnetron sputtering equipment according to claim 22, wherein the copper alloy wires have a diameter of 1 to 2 mm.

25. The magnetron sputtering equipment according to claim 20, wherein the protection plate is a steel plate with a thickness of 1.2 to 1.8 mm.

26. The magnetron sputtering equipment according to claim 19, wherein a mounting hole is disposed on an inner wall of the coating chamber for mounting the mesh shielding plate.

27. The magnetron sputtering equipment according to claim 19, wherein upper and lower inner walls of the coating chamber are provided with fixing members for fixing the mesh shielding plate.

28. The magnetron sputtering equipment according to claim 19, wherein a magnetron sputtering target is disposed in the coating chamber.

29. The magnetron sputtering equipment according to claim 19, wherein the number of the coating chamber is one, two or four.

30. The magnetron sputtering equipment according to claim 28, wherein a distance between the mesh shielding plate and the magnetron sputtering target is 70 to 100 mm.

31. The magnetron sputtering equipment according to claim 19, wherein the mesh shielding plate is disposed on opposite sides of the coating chamber.

32. The magnetron sputtering equipment according to claim 21, wherein the mesh shielding plate is composed of a plurality of meshes having a side length of 0.07 to 4 mm.

33. The magnetron sputtering equipment according to claim 22, wherein the mesh shielding plate is composed of a plurality of meshes having a side length of 0.07 to 4 mm.

34. The magnetron sputtering equipment according to claim 28, wherein a distance between a top of the magnetron sputtering target and an upper inner wall of the vacuum chamber is 12 to 18 mm.

35. The magnetron sputtering equipment according to claim 19, wherein sliding slots are provided at upper and lower inner walls of the coating chamber respectively, sliding rails are provided at two ends of the mesh shielding plate corresponding to the upper and lower inner walls of the coating chamber respectively, and the sliding slots and the sliding rails are slidably connected.

36. The magnetron sputtering equipment according to claim 19, wherein upper and lower inner walls of the coating chamber are provided with hanging members for connecting the mesh shielding plate and the coating chamber.
